(19) United States
(12) Patent Application Publication
(10) Pub. No.: US 2023/0232164 A1
(43) Pub. Date: Jul. 20, 2023

(54) ROLLABLE ELECTROACOUSTIC TRANSDUCER AND ROLLABLE IMAGE DISPLAY DEVICE

(71) Applicant: FUJIFILM Corporation, Tokyo (JP)

(72) Inventor: Tetsu Miyoshi, Minamiashigara-shi (JP)

(73) Assignee: FUJIFILM Corporation, Tokyo (JP)

(21) Appl. No.: 18/189,495

(22) Filed: Mar. 24, 2023

Related U.S. Application Data
(63) Continuation of application No. PCT/JP21/31432, filed on Aug. 27, 2021.

(30) Foreign Application Priority Data
Sep. 25, 2020 (JP) 2020-160849

(51) Int. Cl. H04R 17/00; H04R 1/06

(52) U.S. Cl. CPC H04R 17/00; H04R 1/06; H04R 2499/15

(57) ABSTRACT

An object of the present invention is to provide an electroacoustic transducer and an image display device, each of which can be rolled up and does not need a mechanical mechanism and a driving source. The object is accomplished by providing a vibration plate or display element which can be rolled up, and a convex leaf spring having an arc-shaped cross section in the lateral direction and having a concave side disposed facing one surface of the vibration plate or a non-image-displaying surface of the display element.

### CROSS-REFERENCE TO RELATED APPLICATIONS

This application is a Continuation of PCT International Application No. PCT/JP2021/031432 filed on Aug. 27, 2021, which claims priority under 35 U.S.C. § 119(a) to Japanese Patent Application No. 2020-160849 filed on Sep. 25, 2020. The above applications are hereby expressly incorporated by reference, in their entirety, into the present application.

### BACKGROUND OF THE INVENTION

### 1. Field of the Invention

The present invention relates to an electroacoustic transducer and an image display device, each of which can be rolled up.

### 2. Description of the Related Art

A flexible display using an organic light emitting diode (OLED) and the like has been put into practical use.

Such a flexible display can be, for example, stretched on a plane during use to appreciate a display image, and can be rolled up and stored during non-use, whereby an installation space can be significantly saved. In addition, by rolling the display up, it is easy to carry the display, and in a case where the display is small, it is portable.

Various kinds of image display devices which can be rolled up using such a flexible display have been proposed.

For example, JP2017-198970A describes a rollable image display device (rollable display device) having a main body including a main roller and a link driving unit, a display element (display panel) of which lower end part is coupled to the main roller and which is flexible (soft) and is rolled up around the main roller, and two link assemblies including an upper link frame of which upper end part is connected to the upper end part of the display element, a lower link frame of which lower end part is connected to the link driving unit, a central link connecting portion to which the lower end part of the upper link frame and the upper end part of the lower link frame are independently coupled, and an elastic plate fixed to the lower link frame.

### SUMMARY OF THE INVENTION

According to the rollable image display device as in JP2017-198970A, an installation space can be reduced and the image display device can be easily carried as described above.

Here, even in the rollable image display device, it is necessary to maintain the planarity of a display element at the time of appreciating a display image. Therefore, in rollable image display devices in the related art, a display element is provided with a complicated mechanical mechanism in order to maintain the flatness of the display element at the time of appreciation while enabling the display element to be rolled up.

For example, the above-mentioned image display device described in JP2017-198970A includes two link assemblies having upper and lower link frames and a central link coupling portion to which the link frames are coupled, and further has a link driving unit that drives the two link assemblies.

Therefore, the rollable image display devices in the related art have problems in that the device configurations are complicated and it is difficult to reduce the size and weight.

To solve such problems of the related art, an object of the present invention is to provide a rollable electroacoustic transducer and a rollable image display device, each of which can be easily reduced in size and weight by dispensing with a mechanical mechanism for maintaining the flatness of a display element and the like during use and enabling the rolling-up during non-use and the like.

In order to accomplish such an object, the present invention has the following configurations.

[1] A rollable electroacoustic transducer comprising:

a rollable vibration plate;

a vibration element that causes the vibration plate to violate; and

a convex leaf spring having an arc-shaped cross section in a lateral direction thereof and having a concave side disposed facing one main surface of the vibration plate.

[2] The rollable electroacoustic transducer as described in [1],

in which a wiring line for driving the vibration element is inserted between the convex leaf spring and the vibration plate.

[3] The rollable electroacoustic transducer as described in [1] or [2],

in which the vibration plate has a rectangular shape and the convex leaf spring is provided with a longitudinal direction thereof being in parallel to one side of the vibration plate, and

the rollable electroacoustic transducer further has a tubular member in a slit formed on a side surface thereof, in which an end part of the vibration plate in a direction orthogonal to the longitudinal direction of the convex leaf spring is inserted into the tubular member and the tubular member extends in the same direction as the end part.

[4] The rollable electroacoustic transducer as described in [3],

in which an end part in the longitudinal direction of the convex leaf spring is inserted into the tubular member.

[5] The rollable electroacoustic transducer as described in any one of [1] to [4],

in which the rollable electroacoustic transducer has a cover member that covers the vibration element, and the vibration plate, the vibration element, the cover member, and the convex leaf spring are disposed in this order in a direction orthogonal to a main surface of the vibration plate.

[6] The rollable electroacoustic transducer as described in any one of [1] to [5],

in which the vibration plate is a display element or a projection screen. [7] The rollable electroacoustic transducer as described in any one of [1] to [6],

in which the vibration element has a laminate where a plurality of layers of a piezoelectric film including a piezoelectric layer, electrode layers provided on both sides of the piezoelectric layer, and protective layers covering the electrode layers are laminated.

[8] The rollable electroacoustic transducer as described in [7],

in which the piezoelectric layer of the piezoelectric film is a polymer-based piezoelectric composite material having piezoelectric particles in a polymer material.

[9] The rollable electroacoustic transducer as described in [8],

in which the polymer material of the polymer-based piezoelectric composite material is cyanoethylated polyvinyl alcohol.

[10] A rollable image display device comprising:

a rollable display element; and

a convex leaf spring having an arc-shaped cross section in a lateral direction thereof and having a concave surface disposed facing a non-image-displaying surface of the display element, the convex leaf spring being provided on the non-image-displaying surface side of the display element.

[11] The rollable image display device as described in [10],

in which the convex leaf spring is provided with a longitudinal direction thereof being in parallel to one side of the display element, and

the rollable image display device further has a tubular member in a slit formed on a side surface thereof, in which an end part of the display element in a direction orthogonal to the longitudinal direction of the convex leaf spring is inserted into the tubular member and the tubular member extends in the same direction as the end part.

[12] The rollable image display device as described in [11],

in which an end part in the longitudinal direction of the convex leaf spring is inserted into the tubular member.

[13] The rollable image display device as described in any one of [10] to [12], further comprising a vibration element that vibrates the display element, the vibration element being provided on a non-image-displaying surface side of the display element.

[14] The rollable image display device as described in [13],

in which a wiring line for driving the vibration element is inserted between the convex leaf spring and the display element.

[15] The rollable image display device as described in [13] or [14],

in which the rollable image display device has a cover member that covers the vibration element, and the display element, the vibration element, the cover member, and the convex leaf spring are disposed in this order in a direction orthogonal to an image display surface of the display element.

[16] The rollable image display device as described in any one of [13] to [15],

in which the vibration element has a laminate where a plurality of layers of a piezoelectric film including a piezoelectric layer, electrode layers provided on both sides of the piezoelectric layer, and protective layers covering the electrode layers are laminated.

[17] The rollable image display device as described in [16],

in which the piezoelectric layer of the piezoelectric film is a polymer-based piezoelectric composite material having piezoelectric particles in a polymer material.

[18] The rollable image display device as described in [17],

in which the polymer material of the polymer-based piezoelectric composite material is cyanoethylated polyvinyl alcohol.

According to such the present invention, it is possible to provide a rollable electroacoustic transducer such as a speaker, and a rollable image display device, each of which is reduced in size and weight by dispensing with a mechanical mechanism for enabling the rolling-up during non-use and the like, and maintaining the flatness of a display element and the like during use.

### BRIEF DESCRIPTION OF THE DRAWINGS

FIG. 1 is a view conceptually showing an example of an electroacoustic transducer of an embodiment of the present invention.

FIG. 2 is a view conceptually showing a side surface of the vibration element.

FIG. 3 is a schematic perspective view of a vibration element.

FIG. 4 is a view conceptually showing an example of a piezoelectric film constituting a piezoelectric element.

FIG. 5 is a conceptual view for describing an example of a method for manufacturing a piezoelectric film.

FIG. 6 is a conceptual view for describing an example of the method for manufacturing a piezoelectric film.

FIG. 7 is a conceptual view for describing an example of the method for manufacturing a piezoelectric film.

FIG. 8 is a conceptual view for describing an action of an electroacoustic transducer.

FIG. 9 is a conceptual view for describing an action of an electroacoustic transducer.

FIG. 10 is a view conceptually showing another example of the electroacoustic transducer of the embodiment of the present invention.

FIG. 11 is a view conceptually showing another example of the electroacoustic transducer of the embodiment of the present invention.

FIG. 12 is a conceptual view for describing an action of the electroacoustic transducer shown in FIG. 11.

### DESCRIPTION OF THE PREFERRED EMBODIMENTS

Hereinafter, the rollable electroacoustic transducer and the rollable image display device of embodiments of the present invention will be described in detail based on the suitable embodiments shown in the accompanying drawings.

Descriptions on the configuration requirements which will be described later are made based on representative embodiments of the present invention in some cases, but it should not be construed that the present invention is limited to such embodiments.

In addition, the figures shown below are conceptual views for describing the electroacoustic transducer of the embodiment of the present invention, and the size, the thickness, the shape, the positional relationship, and the like of each member are different from the actual values.

Furthermore, in the present specification, the numerical range represented by “to” means a range including numerical values denoted before and after “to” as a lower limit value and an upper limit value, respectively.

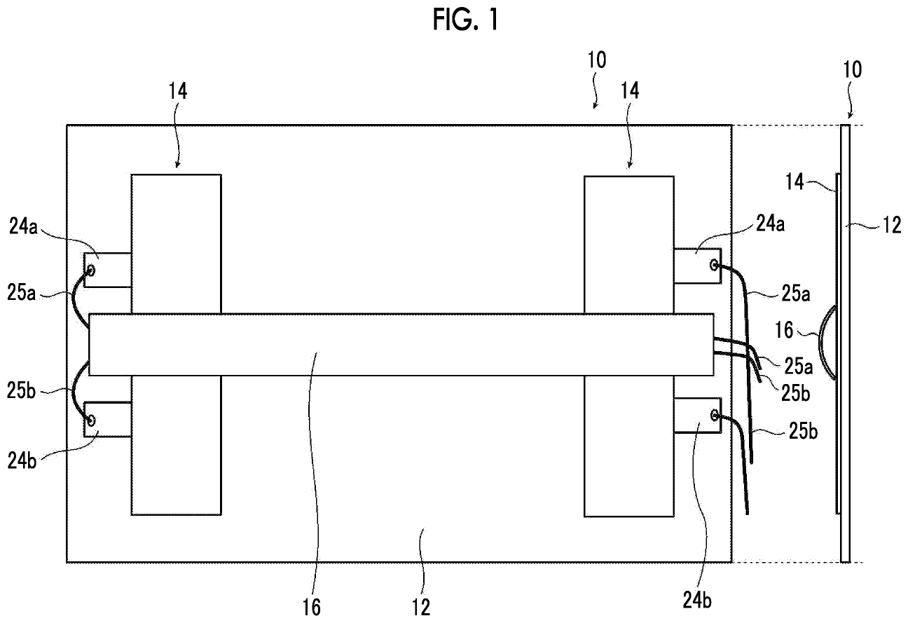

FIG. 1 conceptually shows an example of the rollable electroacoustic transducer of the embodiment of the present invention. In FIG. 1, the left side view is a rear view and the right side view is a side view.

A rollable electroacoustic transducer 10 shown in FIG. 1 includes a vibration plate 12, a vibration element 14, and a convex leaf spring 16. In the following description, the “rollable electroacoustic transducer” is also simply referred to as an “electroacoustic transducer”.

In the electroacoustic transducer 10 of the illustrated example, the vibration element 14 is affixed to one main surface of the vibration plate 12. In addition, the convex leaf spring 16 is fixed to the same main surface of the vibration plate 12 as the vibration element 14 so as to straddle the vibration element 14. Furthermore, the main surface is the maximum surface of a sheet-like material (a plate-like material, a film, or a layer), and is usually on both sides in the thickness direction.

In the electroacoustic transducer of the embodiment of the present invention, the vibration element 14 and the convex leaf spring 16 are not necessarily limited to be provided on the same main surface of the vibration plate 12. That is, in the electroacoustic transducer of the embodiment of the present invention, the vibration element 14 may be provided on one main surface of the vibration plate 12, and the convex leaf spring 16 may be provided on the other main surface of the vibration plate 12.

It should be noted that in the electroacoustic transducer 10 of the embodiment of the present invention, in a case where the vibration element 14 and the convex leaf spring 16 are provided on the same main surface of the vibration plate 12 as in the illustrated example, the vibration plate 12, the vibration element 14, and the convex leaf spring 16 are arranged in this order from the vibration plate 12 side.

That is, in the electroacoustic transducer of the embodiment of the present invention, it is preferable that the convex leaf spring 16 is located on the outermost side in the stacking direction of the vibration plate 12, the vibration element 14, and the convex leaf spring 16. In this regard, the same applies to the image display device of an embodiment of the present invention, which will be described below.

As will be described in detail later, in the electroacoustic transducer 10, the vibration element 14 acts as a so-called exciter that causes the vibration plate 12 to vibrate to output a voice.

That is, in the electroacoustic transducer 10, the vibration element 14 stretches and contracts in the plane direction by applying a driving voltage to the vibration element 14 (a piezoelectric film 24 which will be described later). The stretching and contraction of the vibration element 14 in the plane direction causes the vibration plate 12 to bend, and as a result, the vibration plate 12 vibrates in the thickness direction. The vibration plate 12 outputs a voice due to the vibration in the thickness direction. That is, the vibration plate 12 vibrates according to a magnitude of the voltage (driving voltage) applied to the vibration element 14 to outputs a voice according to the driving voltage applied to the vibration element 14.

As mentioned above, the figure on the left side of FIG. 1 is a rear view. Accordingly, the appreciation of the voice output by the electroacoustic transducer 10 is basically performed on the main surface side of the vibration plate 12 on the side where the vibration element 14 or the like is not disposed. That is, in the electroacoustic transducer 10 shown in FIG. 1, the appreciation of the voice is basically performed from the right side of the figure on the right side of FIG. 1.

In the example shown in FIG. 1, two vibration elements 14 are provided so as to be spaced apart from each other in the longitudinal direction of the vibration plate 12. This corresponds to a stereo reproduction of a voice, one of the vibration elements 14 corresponds to the right channel, and the other vibration element 14 corresponds to the left channel.

Furthermore, in the electroacoustic transducer 10 according to the embodiment of the present invention, the number of vibration elements 14 is not limited to two, and may be one or may have three or more vibration elements 14.

In the electroacoustic transducer 10 according to the embodiment of the present invention, the vibration plate 12 is a sheet-like material (a plate-like material and a film), which is a rollable and flexible, sheet-like material capable of being rolled up from a flat plate shape, and returned to a flat plate-shaped state from the rolling-up state repeatedly.

In the present invention, the vibration plate 12 is not limited, and various sheet-like materials can be used as long as the objects can be rolled up and can vibrate by a known exciter to output a voice.

In one example, resin films consisting of polyethylene terephthalate (PET), polypropylene (PP), polystyrene (PS), polycarbonate (PC), polyphenylene sulfide (PPS), polymethyl methacrylate (PMMA), and polyetherimide (PEI), polyimide (PI), polyethylene naphthalate (PEN), triacetyl cellulose (TAC), a cyclic olefin-based resin, or the like, foamed plastic consisting of foamed polystyrene, foamed styrene, foamed polyethylene, or the like, various corrugated cardboard materials obtained by bonding other paperboards to one or both surfaces of wavy paperboards, wood materials such as a veneer board, leather materials, photographic printing paper, metal materials such as aluminum, brass, and stainless steel, glass materials, various heat dissipation members, and a laminated plate obtained by attaching a plurality of these members to each other are exemplified.

In addition, in the electroacoustic transducer 10 of the embodiment of the present invention, a display device (a display device and a display panel) such as an organic electroluminescence (organic light emitting diode (OLED)) display, an electronic paper, a liquid crystal display, a micro light emitting diode (LED) display, an inorganic electroluminescence display, and a mini LED display can also be suitably used as the vibration plate 12 as long as it can be rolled up.

Further, in the electroacoustic transducer 10 of the embodiment of the present invention, a screen for projection, in which an image is projected from a projecting machine such as a projector, thus displaying an image, can also be suitably used as the vibration plate 12 as long as it can be rolled up.

Furthermore, the electroacoustic transducer of the embodiment of the present invention may be an electroacoustic transducer in which the above-mentioned rollable display element, a projection screen, and the like, are attached to the rollable vibration plate 12 consisting of a resin film and the like as mentioned above.

In addition, in the electroacoustic transducer 10 according to the embodiment of the present invention, the shape of the vibration plate 12 is not limited to the rectangular shape shown in the illustrated example, and various shapes such as a circular shape, an elliptical shape, and a polygonal shape other than the rectangular shape can be used.

As mentioned above, the vibration element 14 is affixed to the vibration plate 12. The vibration element 14 is a so-called exciter that causes the vibration plate 12 to vibrate, thereby outputting a voice to the vibration plate 12.

The vibration element 14 is not limited and various types of vibration elements that act as an exciter (audio exciter) that causes the vibration plate 12 to vibrate, thereby outputting a voice, can be used.

Here, the electroacoustic transducer 10 of the embodiment of the present invention is a rollable electroacoustic transducer that uses the rollable vibration plate 12. Therefore, it is preferable that the vibration element 14 affixed to the vibration plate 12 also has sufficient flexibility to follow the rolling-up of the vibration plate 12.

In consideration of this point, it is preferable that the vibration element 14 is composed of a piezoelectric film in which electrode layers are provided on both surfaces of the piezoelectric layer. In addition, it is more preferable that the piezoelectric film further has protective films that cover the electrode layers to protect the electrode layers and the like.

Further, the vibration element 14 may have only one layer of the piezoelectric film. However, in order to bend the vibration plate 12 with a sufficient force to vibrate by expressing a sufficient stretching force, it is preferable that the vibration plate 12 is a vibration plate where a plurality of layers of the piezoelectric film are laminated.

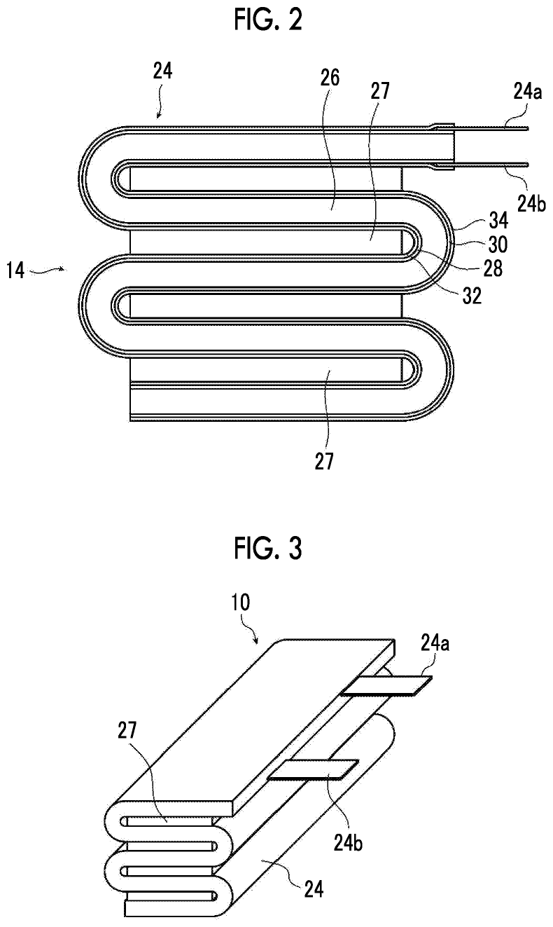

FIG. 2 and FIG. 3 conceptually show an example of the vibration element 14 in which such a piezoelectric film is laminated.

In the vibration element 14, a piezoelectric film 24 having a first electrode layer 28 on one surface of a piezoelectric layer 26 and a second electrode layer 30 on the other surface is used. In addition, in a preferred embodiment, the piezoelectric film 24 covers the first electrode layer 28 to have the first protective layer 32, and covers the second electrode layer 30 to have the second protective layer 34.

The vibration element 14 in the example illustrated in the figure may have five layers of the piezoelectric film 24 laminated by folding the piezoelectric film 24 four times. In addition, the adjacent layers of the piezoelectric film 24 laminated are affixed to each other by an affixing layer 27.

FIG. 2 is a side view of the vibration element 14 of the illustrated example, in which the vibration element 14 is viewed from above (or below) in the figure of FIG. 1. That is, FIG. 1 is a view of the vibration element 14 as viewed from above in FIG. 2. Therefore, in the figure on the left side of FIG. 1, the vibration element 14 has the piezoelectric film 24 folded back in the lateral direction in the figure. On the other hand, in the figure on the right side of FIG. 1, the vibration element 14 has the piezoelectric film 24 folded back in the vertical direction in the figure.

FIG. 3 is a schematic perspective view of the vibration element 14. In FIG. 3, in order to simplify the figure, the piezoelectric film 24 is shown as one layer.

Furthermore, in the electroacoustic transducer 10 of the embodiment of the present invention, the vibration element 14 where the piezoelectric film 24 is laminated is not limited to those where five layers of the piezoelectric film 24 are laminated. That is, in the electroacoustic transducer 10 of the embodiment of the present invention, the vibration element 14 may be a vibration element where four or less layers of the piezoelectric film 24 obtained by folding the piezoelectric film 24 back three or less times are laminated. Alternatively, in the electroacoustic transducer 10 of the embodiment of the present invention, the vibration element 14 may be a vibration element where six or more layers of the piezoelectric film 24 obtained by folding the piezoelectric film 24 five or more times are laminated.

Although being described later, by laminating a plurality of layers of the piezoelectric film 24 in this manner, it is possible to bend the vibration plate with a larger force, as compared with a case where one sheet of the piezoelectric film 24 is used. In addition, the electrode can be extracted in one place by the lamination by folding one sheet of the piezoelectric film 24, and the configuration of the electroacoustic transducer 10 can be simplified.

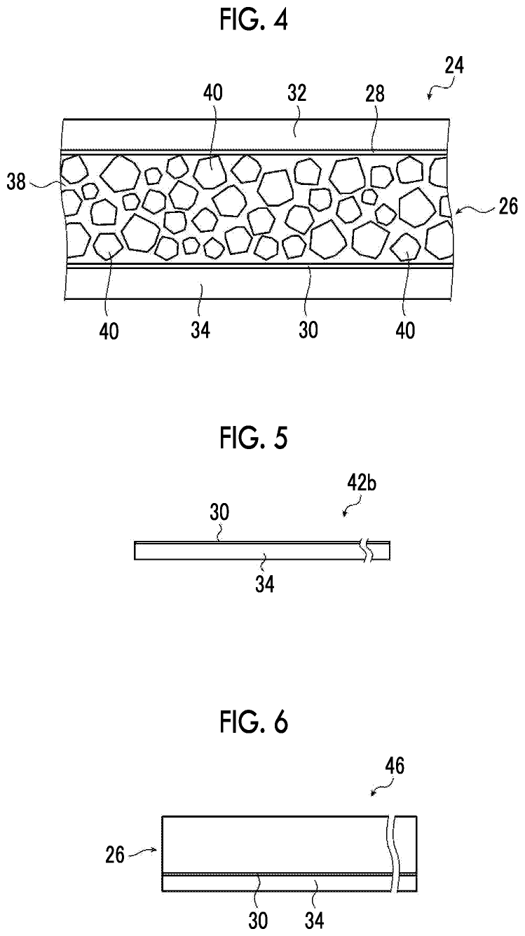

FIG. 4 is a cross-sectional view conceptually showing an example of the piezoelectric film 24. In FIG. 4 and the like, hatching will be omitted in order to clarify the configuration by simplifying the drawing.

Furthermore, in the following description, a “cross section” indicates a cross section of a piezoelectric film in the thickness direction unless otherwise specified. The thickness direction of the piezoelectric film is a lamination direction of each layer.

A piezoelectric film 24 shown in FIG. 4 includes a piezoelectric layer 26, a first electrode layer 28 laminated on one surface of the piezoelectric layer 26, a first protective layer 32 laminated on the first electrode layer 28, a second electrode layer 30 laminated on the other surface of the piezoelectric layer 26, and a second protective layer 34 laminated on the second electrode layer 30.

In the piezoelectric film 24, the piezoelectric layer 26 is not limited, and various known piezoelectric layers such as a layer made of polyvinylidene fluoride (PVDF) can be used.

In the piezoelectric film 24, as conceptually shown in FIG. 4, the piezoelectric layer 26 is preferably a polymer-based piezoelectric composite material including the piezoelectric particles 40 in the polymer matrix 38 including the polymer material.

Here, it is preferable that the polymer-based piezoelectric composite material (the piezoelectric layer 26) has the following requirements. Further, in the present invention, room temperature is in a range of 0° C. to 50° C.

(i) Flexibility

For example, in a case of being gripped in a state of being loosely bent like a document such as a newspaper and a magazine as a portable device, the piezoelectric film is continuously subjected to large bending deformation from the outside at a relatively slow vibration of less than or equal to a few Hz. In this case, in a case where the polymer-based piezoelectric composite material is hard, a large bending stress is generated to that extent, and a crack is generated at the interface between a polymer matrix and piezoelectric particles, which may lead to breakage. Accordingly, the polymer-based piezoelectric composite material is required to have suitable flexibility. In addition, in a case where strain energy is diffused into the outside as heat, the stress is able to be relieved. Accordingly, a loss tangent of the polymer-based piezoelectric composite material is required to be suitably large.

(ii) Acoustic Quality

In a speaker, the piezoelectric particles vibrate at a frequency of an audio band of 20 Hz to 20 kHz, and the vibration energy causes the entire vibration plate (polymer-based piezoelectric composite material) to vibrate integrally so that a voice is reproduced. Accordingly, in order to increase the transmission efficiency of the vibration energy, the polymer-based piezoelectric composite material is required to have an appropriate hardness. In addition, in a case where the frequency characteristics of the speaker are smooth, an amount of change in acoustic quality in a case where the lowest resonance frequency f₀ is changed in association with a change in the curvature of the speaker decreases. Accordingly, the loss tangent of the polymer-based piezoelectric composite material is required to be suitably large.

It is known that the lowest resonance frequency f₀ of the vibration plate for a speaker is represented by the following equation. Here, s represents the stiffness of the vibration system and m represents the mass.

$$Lowest resonance frequency : {f}_{0} = \frac{1}{2 π} \sqrt{\frac{s}{m}} \qquad [ Equation 1 ]$$

Here, as a degree of curvature of the piezoelectric film, that is, a radius of curvature of the curved part increases, a mechanical stiffness s decreases, whereby a lowest resonance frequency f₀ decreases. That is, an acoustic quality (a volume and frequency characteristics) of the speaker changes depending on the radius of curvature of the piezoelectric film.

As described above, the polymer-based piezoelectric composite material is required to exhibit a behavior of being rigid with respect to a vibration at 20 Hz to 20 kHz and being flexible with respect to a vibration of less than or equal to a few Hz. In addition, the loss tangent of a polymer-based piezoelectric composite material is required to be suitably large with respect to a vibration at all frequencies of 20 kHz or less.

In general, a polymer solid has viscoelasticity relieving mechanism, and molecular movement having a large scale is observed as a decrease (relief) in a storage elastic modulus (Young's modulus) or a maximal value (absorption) in a loss elastic modulus along with an increase in a temperature or a decrease in a frequency. Among these, the relief due to a micro-brownian motion of a molecular chain in an amorphous region is referred to as main dispersion, and an extremely large relieving phenomenon is observed. A temperature at which this main dispersion occurs is a glass transition point (Tg), and the viscoelasticity relieving mechanism is most remarkably observed.

In the polymer-based piezoelectric composite material (piezoelectric layer 26), the polymer-based piezoelectric composite material exhibiting a behavior of being rigid with respect to a vibration of 20 Hz to 20 kHz and being flexible with respect to a vibration of less than or equal to a few Hz is realized by using a polymer material whose glass transition point is room temperature, that is, a polymer material having a viscoelasticity at room temperature as a matrix. In particular, from the viewpoint that such a behavior is suitably exhibited, it is preferable that the polymer material in which the glass transition point Tg at a frequency of 1 Hz is at room temperature is used for a matrix of the polymer-based piezoelectric composite material.

In the polymer material serving as a polymer matrix 38, it is preferable that the maximal value of a loss tangent tan δ at a frequency of 1 Hz according to a dynamic viscoelasticity test at room temperature is 0.5 or more.

In this manner, in a case where the polymer-based piezoelectric composite material is slowly bent due to an external force, stress concentration on the interface between the polymer matrix and the piezoelectric particles at most bending moment portion is relieved, and thus, satisfactory flexibility can be expected.

In addition, in the polymer material serving as the polymer matrix 38, it is preferable that a storage elastic modulus (E′) at a frequency of 1 Hz according to the dynamic viscoelasticity measurement is 100 MPa or more at 0° C. and 10 MPa or less at 50° C.

In this manner, it is possible to reduce a bending moment which is generated in a case where the polymer-based piezoelectric composite material is slowly bent due to the external force, and it is also possible to make the polymer-based piezoelectric composite material rigid with respect to an acoustic vibration of 20 Hz to 20 kHz.

In addition, it is more suitable that the relative permittivity of the polymer material serving as the polymer matrix 38 is 10 or more at 25° C. In this manner, in a case where a voltage is applied to the polymer-based piezoelectric composite material, a higher electric field is applied to the piezoelectric particles in the polymer matrix, whereby a large deformation amount can be expected.

However, in consideration of securing good moisture resistance, or the like, it is suitable that the relative permittivity of the polymer material is 10 or less at 25° C.

Suitable examples of the polymer material that satisfies such conditions include cyanoethylated polyvinyl alcohol (cyanoethylated PVA), polyvinyl acetate, polyvinylidene chloride-co-acrylonitrile, a polystyrene-vinyl polyisoprene block copolymer, polyvinyl methyl ketone, and polybutyl methacrylate.

In addition, as these polymer materials, a commercially available product such as HYBRAR 5127 (manufactured by Kuraray Co., Ltd.) can be suitably used.

Among these, it is preferable to use a polymer material having a cyanoethyl group and particularly preferable to use cyanoethylated PVA as the polymer material constituting the polymer matrix 38. That is, in the piezoelectric film 24, it is preferable to use a polymer material having a cyanoethyl group and particularly preferable to use cyanoethylated PVA as the polymer matrix 38 of the piezoelectric layer 26.

In the following description, the above-described polymer materials typified by cyanoethylated PVA will also be collectively referred to as the “polymer material having a viscoelasticity at room temperature”.

Furthermore, the polymer material having a viscoelasticity at room temperature may be used alone or in combination of two or more kinds thereof (mixture).

In the piezoelectric film 24, a plurality of polymer materials may be used in combination, as necessary, for the polymer matrix 38 of the piezoelectric layer 26.

That is, for the purpose of adjustment of dielectric characteristics or mechanical characteristics, and the like, other dielectric polymer materials may be added to the polymer matrix 38 constituting the polymer-based piezoelectric composite material in addition to the polymer material having a viscoelasticity at room temperature, as necessary.

Examples of the dielectric polymer material that can be added thereto include fluorine-based polymers such as polyvinylidene fluoride, a vinylidene fluoride-tetrafluoroethylene copolymer, a vinylidene fluoride-trifluoroethylene copolymer, a polyvinylidene fluoride-trifluoroethylene copolymer, and a polyvinylidene fluoride-tetrafluoroethylene copolymer; polymers having a cyano group or a cyanoethyl group, such as a vinylidene cyanide-vinyl acetate copolymer, cyanoethyl cellulose, cyanoethyl hydroxysaccharose, cyanoethyl hydroxycellulose, cyanoethyl hydroxypullulan, cyanoethyl methacrylate, cyanoethyl acrylate, cyanoethyl hydroxyethyl cellulose, cyanoethyl amylose, cyanoethyl hydroxypropyl cellulose, cyanoethyl dihydroxypropyl cellulose, cyanoethyl hydroxypropyl amylose, cyanoethyl polyacrylamide, cyanoethyl polyacrylate, cyanoethyl pullulan, cyanoethyl polyhydroxymethylene, cyanoethyl glycidol pullulan, cyanoethyl saccharose, and cyanoethyl sorbitol; and synthetic rubber such as nitrile rubber and chloroprene rubber.

Among those, the polymer material having a cyanoethyl group is suitably used.

In addition, in the polymer matrix 38 of the piezoelectric layer 26, the number of these dielectric polymer materials is not limited to one, and a plurality of kinds of dielectric polymer materials may be added.

In addition, in the piezoelectric layer 26, for the purpose of adjusting the glass transition point Tg of the polymer matrix 38, a thermoplastic resin such as a vinyl chloride resin, polyethylene, polystyrene, a methacrylic resin, polybutene, or isobutylene, and a thermosetting resin such as a phenol resin, a urea resin, a melamine resin, an alkyd resin, or mica may also be added, in addition to the dielectric polymer materials.

Furthermore, in the piezoelectric layer 26, for the purpose of improving the pressure sensitive adhesiveness, a viscosity imparting agent such as rosin ester, rosin, terpene, terpene phenol, and a petroleum resin may be added.

In the polymer matrix 38 of the piezoelectric layer 26, the addition amount in a case of adding polymer materials other than the polymer material having a viscoelasticity at room temperature is not particularly limited, but is preferably set to 30% by mass or less in terms of a proportion of the polymer materials in the polymer matrix 38.

In this manner, the characteristics of the polymer material to be added can be exhibited without impairing the viscoelasticity relieving mechanism in the polymer matrix 38, whereby preferred results, for example, an increase in a permittivity, improvement of heat resistance, and improvement of adhesiveness between the piezoelectric particles 40 and the electrode layer can be obtained.

The polymer-based piezoelectric composite material serving as the piezoelectric layer 26 includes the piezoelectric particles 40 in the polymer matrix. The piezoelectric particles 40 are dispersed in a polymer matrix, and preferably uniformly (substantially uniformly) dispersed therein.

It is preferable that the piezoelectric particles 40 consist of ceramic particles having a perovskite type or wurtzite type crystal structure.

Examples of the ceramics particles constituting the piezoelectric particles 40 include lead zirconate titanate (PZT), lead lanthanum zirconate titanate (PLZT), barium titanate (BaTiO₃), zinc oxide (ZnO), and a solid solution (BFBT) of barium titanate and bismuth ferrite (BiFe₃).

The particle diameters of the piezoelectric particles 40 may be appropriately selected according to the size and the application of the piezoelectric film 24. The particle diameters of the piezoelectric particles 40 are preferably 1 to 10 μm.

By setting the particle diameters of the piezoelectric particles 40 to be in the range, preferred results from the viewpoints of achieving both excellent piezoelectric characteristics and flexibility, and the like can be obtained.

In the piezoelectric film 24, a ratio between the amount of the polymer matrix 38 and the amount of the piezoelectric particles 40 in the piezoelectric layer 26 may be appropriately set according to the size or the thickness of the piezoelectric film 24 in the plane direction, the application of the piezoelectric film 24, the characteristics required for the piezoelectric film 24, and the like.

A volume fraction of the piezoelectric particles 40 in the piezoelectric layer 26 is preferably in a range of 30% to 80%, and more preferably in a range of 50% to 80%.

By setting the ratio between the amount of the polymer matrix 38 and the amount of the piezoelectric particles 40 to be in the range, preferred results from the viewpoints of achieving both excellent piezoelectric characteristics and flexibility, and the like can be obtained.

In the piezoelectric film 24, a thickness of the piezoelectric layer 26 is not limited and may be appropriately set according to the size of the piezoelectric film 24, the application of the piezoelectric film 24, the characteristics required for the piezoelectric film 24, and the like.

The thickness of the piezoelectric layer 26 is preferably 8 to 300 more preferably 8 to 200 still more preferably 10 to 150 and particularly preferably 15 to 100 μm.

By setting the thickness of the piezoelectric layer 26 to be in the range, it is possible to obtain preferred results from the viewpoints of achieving both ensuring of the rigidity and appropriate flexibility, and the like.

It is preferable that the piezoelectric layer 26 is subjected to a polarization treatment (poling) in the thickness direction. The polarization treatment will be described in detail later.

Moreover, in the piezoelectric film 24, the piezoelectric layer 26 is not limited to the polymer-based piezoelectric composite material including the piezoelectric particles 40 in the polymer matrix 38 consisting of a polymer material having viscoelasticity at room temperature, such as cyanoethylated PVA, as described above.

That is, in the piezoelectric film 24, various known piezoelectric layers can be used as the piezoelectric layer 26.

By way of an example, a polymer-based piezoelectric composite material including the same piezoelectric particles 40 in a matrix including a dielectric polymer material such as polyvinylidene fluoride, a vinylidene fluoride-tetrafluoroethylene copolymer, and a vinylidene fluoride-trifluoroethylene copolymer mentioned above, a piezoelectric layer consisting of polyvinylidene fluoride, a piezoelectric layer consisting of a fluororesin other than polyvinylidene fluoride, a piezoelectric layer obtained by laminating a film consisting of poly-L lactic acid and a film consisting of poly-D lactic acid, and the like are also available.

However, from the viewpoints, for example, that the polymer-based piezoelectric composite material can behave hard for vibrations at 20 Hz to 20 kHz and behave softly for slow vibrations at several Hz or less as described above, can have excellent acoustic characteristics, excellent flexibility, and is capable of obtaining a vibration element 14 having excellent flexibility and suitably following the rolling-up of the vibration plate 12, a polymer-based piezoelectric composite material including the piezoelectric particles 40 in the polymer matrix 38 consisting of a polymer material having viscoelasticity at room temperature, such as cyanoethylated PVA, is suitably used as the piezoelectric layer 26.

The piezoelectric film 24 shown in FIG. 4 has a configuration to have a second electrode layer 30 on one surface of such a piezoelectric layer 26, a second protective layer 34 on a surface of the second electrode layer 30, a first electrode layer 28 on the other surface of the piezoelectric layer 26, and a first protective layer 32 on a surface of the first electrode layer 28. In the piezoelectric film 24, the first electrode layer 28 and the second electrode layer 30 form an electrode pair.

In other words, the laminated film constituting the piezoelectric film 24 has a configuration in which both surfaces of the piezoelectric layer 26 are interposed between electrode pairs, that is, the first electrode layer 28 and the second electrode layer 30, and further interposed between the first protective layer 32 and the second protective layers 34.

In this manner, the region interposed between the first electrode layer 28 and the second electrode layer 30 is driven according to the applied voltage.

In the present invention, the first and second electrodes in the first electrode layer 28, the second electrode layer 30, and the like are added for convenience in order to describe the piezoelectric film 24.

Therefore, “first” and “second” in the piezoelectric film 24 have no technical meanings and are irrelevant to the actual usage state.

The piezoelectric film 24 may have, in addition to those layers, for example, an affixing layer for affixing the electrode layer and the piezoelectric layer 26 to each other, and an affixing layer for affixing the electrode layer and the protective layer to each other.

The affixing agent may be an adhesive or a pressure sensitive adhesive. In addition, the same material as the polymer material obtained by removing the piezoelectric particles 40 from the piezoelectric layer 26, that is, the polymer matrix 38 can also be suitably used as the affixing agent. Furthermore, the affixing layer may be provided on both the first electrode layer 28 side and the second electrode layer 30 side, or may also be provided on only one of the first electrode layer 28 side and the second electrode layer 30 side.

In the piezoelectric film 24, the first protective layer 32 and the second protective layer 34 play a role to impart moderate rigidity and mechanical strength to the piezoelectric layer 26 while covering the first electrode layer 28 and the second electrode layer 30. That is, in the piezoelectric film 24, the piezoelectric layer 26 including the polymer matrix 38 and the piezoelectric particles 40 exhibits extremely excellent flexibility for bending deformation at a slow vibration. In contrast, the piezoelectric layer may have insufficient rigidity, mechanical strength, and the like, depending on the applications. As a compensation for this, the piezoelectric film 24 is provided with the first protective layer 32 and the second protective layer 34.

The first protective layer 32 and the second protective layer 34 have the same configuration despite of different disposition positions. Accordingly, in the following description, in a case where it is not necessary to distinguish the first protective layer 32 from the second protective layer 34, both members are collectively referred to as a protective layer.

The protective layer is not limited, various sheet-like materials can be used as the protective layer, and suitable examples thereof include various resin films. Among these, from the viewpoints of excellent mechanical characteristics and heat resistance, a resin film consisting of polyethylene terephthalate (PET), polypropylene (PP), polystyrene (PS), polycarbonate (PC), polyphenylene sulfide (PPS), polymethyl methacrylate (PMMA), polyetherimide (PEI), polyimide (PI), polyamide (PA), polyethylene naphthalate (PEN), triacetyl cellulose (TAC), and a cyclic olefin-based resin is suitably used.

A thickness of the protective layer is not limited. In addition, the thicknesses of the first protective layer 32 and the second protective layer 34 are basically the same as each other, but may be different from each other.

Here, in a case where the rigidity of the protective layer is extremely high, not only is the stretching and contraction of the piezoelectric layer 26 constrained, but also the flexibility is impaired. Therefore, it is advantageous that the thickness of the protective layer decreases, except for a case where the mechanical strength, or excellent handleability for a sheet-like material is required.

In a case where the thickness of the first protective layer 32 and the thickness of the second protective layer 34 are each twice or less the thickness of the piezoelectric layer 26, preferred results from the viewpoints of achieving both ensuring of the rigidity and moderate flexibility, and the like can be obtained.

For example, in a case where the thickness of the piezoelectric layer 26 is 50 μm, and the first protective layer 32 and the second protective layer 34 consist of PET, the thickness of the first protective layer 32 and the thickness of the second protective layer 34 are each preferably 100 μm or less, more preferably 50 μm or less, and still more preferably 25 μm or less.

Moreover, in the present invention, the first protective layer 32 and the second protective layer 34 are provided in a preferred aspect, and are not an essential configuration requirement. That is, in the electroacoustic transducer of the embodiment of the present invention, the piezoelectric film may have the first protective layer 32 or the second protective layer 34, or may also have neither of the first protective layer 32 nor the second protective layer 34.

However, in consideration of the strength, handleability, protection of the electrode layer, and the like of the piezoelectric film 24, it is preferable that the piezoelectric film has both the first protective layer 32 and the second protective layer 34 as shown in the example illustrated in the figure.

In the piezoelectric film 24, the first electrode layer 28 is formed between the piezoelectric layer 26 and the first protective layer 32, and the second electrode layer 30 is formed between the piezoelectric layer 26 and the second protective layer 34. The first electrode layer 28 and the second electrode layer 30 are provided to apply an electric field to the piezoelectric film 24 (piezoelectric layer 26).

The first electrode layer 28 and the second electrode layer 30 are basically the same, except that the positions are different. Accordingly, in the following description, in a case where it is not necessary to distinguish the second electrode layer 30 from the first electrode layer 28, both members are collectively referred to as an electrode layer.

In the piezoelectric film, a material for forming the electrode layer is not limited and various conductors can be used as the material. Specific examples thereof include conductive polymers such as carbon, palladium, iron, tin, aluminum, nickel, platinum, gold, silver, copper, chromium, molybdenum, alloys thereof, indium tin oxide, and polyethylene dioxythiophene-polystyrene sulfonic acid (PEDOT/PPS).

Among those, copper, aluminum, gold, silver, platinum, and indium tin oxide are suitably exemplified. Among these, from the viewpoints of conductivity, cost, and flexibility, copper is more preferable.

In addition, a method of forming the electrode layer is not limited, and various known methods, for example, a film forming method such as a vapor-phase deposition method (a vacuum film forming method) such as vacuum vapor deposition and sputtering, film formation using plating, a method of affixing a foil formed of the material, and a coating method can be used.

Among these, particularly from the viewpoint of ensuring the flexibility of the piezoelectric film 24, a thin film made of copper or aluminum formed by vacuum vapor deposition is suitably used as the electrode layer. Among these, in particular, a thin film made of copper formed by vacuum vapor deposition is suitably used.

The thickness of the first electrode layer 28 and the thickness of the second electrode layer 30 are not limited. In addition, the thicknesses of the first electrode layer 28 and the thicknesses of the second electrode layer 30 may basically be the same as or different from each other.

Here, similarly to the protective layer described above, in a case where the rigidity of the electrode layer is extremely high, not only is the stretching and contraction of the piezoelectric layer 26 constrained, but also the flexibility is impaired. Therefore, it is advantageous that the thickness of the electrode layer is reduced in a case where the electric resistance is not excessively high.

It is suitable that a product of the thicknesses of the electrode layer of the piezoelectric film 24 and the Young's modulus thereof is less than a product of the thickness of the protective layer and the Young's modulus thereof since the flexibility is not considerably impaired.

For example, in a case of a combination consisting of the protective layer formed of PET (Young's modulus: approximately 6.2 GPa) and the electrode layer consisting of copper (Young's modulus: approximately 130 GPa), the thickness of the electrode layer is preferably 1.2 μm or less, and more preferably 0.3 μm or less in a case of assuming that the thickness of the protective layer is 25 μm, and among these, the thickness of 0.1 μm or less is preferable.

The piezoelectric film 24 has a configuration in which the piezoelectric layer 26 is interposed between the first electrode layer 28 and the second electrode layer 30, and the laminate is further interposed between the first protective layer 32 and the second protective layer 34.

In such a piezoelectric film 24, it is preferable that the maximal value at which the loss tangent (tan δ) at a frequency of 1 Hz according to dynamic viscoelasticity measurement is 0.1 or more is present at room temperature.

In this manner, even in a case where the piezoelectric film 24 is subjected to large bending deformation from the outside at a relatively slow vibration of less than or equal to a few Hz, it is possible to effectively diffuse the strain energy to the outside as heat, whereby it is possible to prevent a crack from being generated on the interface between the polymer matrix and the piezoelectric particles.

In the piezoelectric film 24, it is preferable that the storage elastic modulus (E′) at a frequency of 1 Hz according to the dynamic viscoelasticity measurement is 10 to 30 GPa at 0° C., and 1 to 10 GPa at 50° C.

In this manner, the piezoelectric film 24 may have large frequency dispersion in the storage elastic modulus (E′) at room temperature. That is, the piezoelectric film 24 is able to be rigid with respect to a vibration of 20 Hz to 20 kHz, and is able to be flexible with respect to a vibration of less than or equal to a few Hz.

In the piezoelectric film 24, it is preferable that the product of the thickness and the storage elastic modulus (E′) at a frequency of 1 Hz according to the dynamic viscoelasticity measurement is in a range of 1.0×10⁶ to 2.0×10⁶ N/m at 0° C. and in a range of 1.0×10⁵ to 1.0×10⁶ N/m at 50° C.

In this manner, the piezoelectric film 24 may have moderate rigidity and mechanical strength within a range not impairing the flexibility and the acoustic characteristics.

Furthermore, in the piezoelectric film 24, it is preferable that the loss tangent (Tan δ) at a frequency of 1 kHz at 25° C. is 0.05 or more in a master curve obtained from the dynamic viscoelasticity measurement.

Next, an example of the method for producing the piezoelectric film 24 will be described with reference to FIGS. 5 to 7.

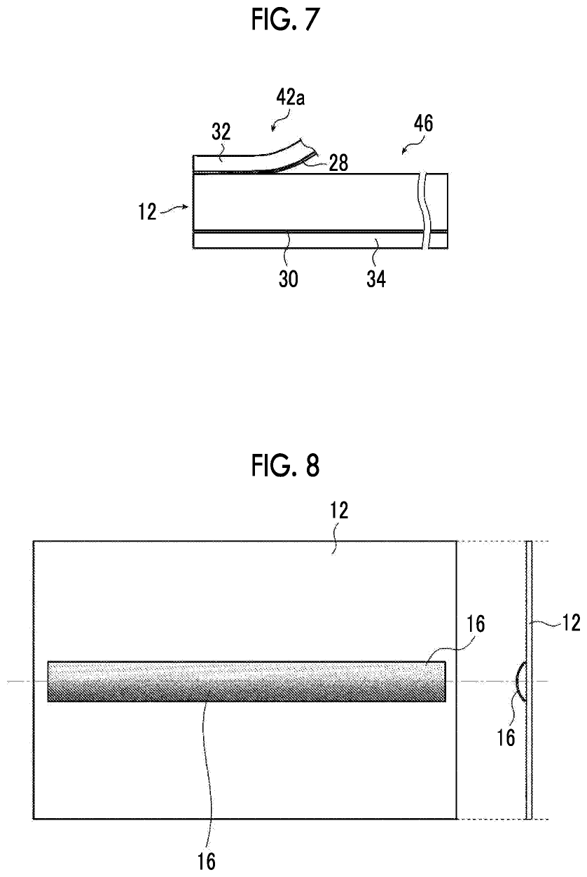

First, a laminate 42b in which the second electrode layer 30 is formed on a surface of the second protective layer 34, as conceptually shown in FIG. 5, is prepared. Furthermore, a laminate 42a in which the first electrode layer 28 is formed on a surface of the first protective layer 32, as conceptually shown in FIG. 7, is prepared.

The laminate 42b may be manufactured by forming a copper thin film or the like as the second electrode layer 30 on a surface of the second protective layer 34 by vacuum vapor deposition, sputtering, plating, or the like. Similarly, the laminate 42a may be manufactured by forming a copper thin film or the like as the first electrode layer 28 on a surface of the first protective layer 32 by vacuum vapor deposition, sputtering, plating, or the like.

Alternatively, a commercially available sheet-like material in which a copper thin film or the like is formed on a protective layer may be used as the laminate 42b and/or the laminate 42a.

The laminate 42b and the laminate 42a may be the same as or different from each other.

Furthermore, in a case where, for example, the protective layer is extremely thin and the handleability is poor, a protective layer with a separator (temporary support) may be used, as necessary. Moreover, a PET film having a thickness of 25 μm to 100 μm or the like can be used as the separator. The separator may be removed after thermal compression bonding of the electrode layer and the protective layer.

Next, as conceptually shown in FIG. 6, a piezoelectric layer 26 is formed on the second electrode layer 30 of the laminate 42b to manufacture a piezoelectric laminate 46 in which the laminate 42b and the piezoelectric layer 26 are laminated.

The piezoelectric layer 26 may be formed by a known method according to the piezoelectric layer 26.

For example, in a case of the piezoelectric layer (polymer-based piezoelectric composite layer) in which the piezoelectric particles 40 are dispersed in the polymer matrix 38 shown in FIG. 4, the piezoelectric layer is manufactured as follows by way of an example.

First, the coating material is prepared by dissolving the above-mentioned polymer material such as cyanoethylated PVA in an organic solvent, adding the piezoelectric particles 40 such as PZT particles thereto, and stirring the solution. The organic solvent is not limited, and various organic solvents such as dimethylformamide (DMF), methyl ethyl ketone, and cyclohexanone can be used.

In a case where the laminate 42b is prepared and the coating material is prepared, the coating material is cast (applied) onto the laminate 42b, and the organic solvent is evaporated and dried. In this manner, a piezoelectric laminate 46 having a second electrode layer 30 on the second protective layer 34, and having the piezoelectric layer 26 laminated on the second electrode layer 30, as shown in FIG. 6, is manufactured.

A casting method of the coating material is not limited, and any of known methods (coating devices) such as a bar coater, a slide coater, and a doctor knife is available.

Alternatively, in a case where the polymer material is a material that can be heated and melted, the piezoelectric laminate 46 as shown in FIG. 7 may be manufactured by heating and melting the polymer material to prepare a melt obtained by adding the piezoelectric particles 40 to the melted material, extruding the melt on the laminate 42b shown in FIG. 5 in a sheet shape by carrying out extrusion molding or the like, and cooling the laminate.

Furthermore, as described above, in the piezoelectric film 24, a polymer-based piezoelectric material such as PVDF may be added to the polymer matrix 38 in addition to the polymer material having a viscoelasticity at room temperature.

In a case where the polymer-based piezoelectric material is added to the polymer matrix 38, the polymer-based piezoelectric material to be added to the coating material may be dissolved. Alternatively, the polymer-based piezoelectric material to be added may be added to the heated and melted polymer material having a viscoelasticity at room temperature so that the polymer-based piezoelectric material is heated and melted.

After forming the piezoelectric layer 26, a calendaring treatment may be performed, as necessary. A calendaring treatment may be performed once or multiple times.

As is well known, the calendaring treatment is a treatment in which the surface to be treated is pressed while being heated by a heating press, a heating roller, or the like to flatten the surface.

In addition, the piezoelectric layer 26 of the piezoelectric laminate 46 having the second electrode layer 30 on the second protective layer 34 and the piezoelectric layer 26 formed on the second electrode layer 30 is subjected to a polarization treatment (poling).

A method of performing a polarization treatment on the piezoelectric layer 26 is not limited, and a known method can be used. Examples of the method include electric field poling in which a DC electric field is directly applied to a target to be subjected to the polarization treatment. Furthermore, in a case of performing the electric field poling, the first electrode layer 28 may be formed before the polarization treatment, and the electric field poling treatment may be performed using the first electrode layer 28 and the second electrode layer 30.

In addition, in a case where the piezoelectric film 24 is produced, in the polarization treatment, the polarization is performed in the thickness direction of the piezoelectric layer 26, not in the plane direction.

Next, as conceptually shown in FIG. 7, the laminate 42a which has been prepared in advance is laminated on the piezoelectric layer 26 side of the piezoelectric laminate 46 such that the first electrode layer 28 is directed toward the piezoelectric layer 26.

Furthermore, the laminate is subjected to thermal compression bonding using a heating press device, heating rollers, or the like such that the laminate is interposed between the first protective layer 32 and the second protective layer 34, thereby bonding the piezoelectric laminate 46 and the laminate 42a.

In this manner, the piezoelectric film 24 consisting of the piezoelectric layer 26, the first electrode layer 28 and the second electrode layer 30 provided on both surfaces of the piezoelectric layer 26, and the first protective layer 32 and the second protective layer 34 formed on a surface of the electrode layer is manufactured.

The piezoelectric film 24 which is manufactured by performing such a manufacturing step is polarized in the thickness direction instead of the plane direction, and thus, excellent piezoelectric characteristics are obtained even in a case where the stretching treatment is not performed after the polarization treatment. Therefore, the piezoelectric film 24 has no in-plane anisotropy as a piezoelectric characteristic, and stretches and contracts isotropically in all directions in the plane direction in a case where a driving voltage is applied.

As mentioned above, the vibration element 14 in the example illustrated in the figure has five layers of the piezoelectric film laminated by folding the piezoelectric film 24 four times. In addition, the adjacent layers of the piezoelectric film 24 by the lamination are affixed to each other by the affixing layer 27 in a preferred aspect.

In the present invention, as the affixing layer 27, various known affixing agents (affixing materials) can be used as long as the adjacent layers of the piezoelectric film 24 can be affixed.

Therefore, the affixing layer 27 may be a layer consisting of an adhesive (adhesive material), a layer consisting of a pressure sensitive adhesive (pressure sensitive adhesive material), or a layer consisting of a material having characteristics of both an adhesive and a pressure sensitive adhesive. The adhesive is an affixing agent which has fluidity upon affixing and then turns into a solid. The pressure sensitive adhesive is an affixing agent which is a gel-like (rubber-like) soft solid upon affixing, with the gel-like state not changing even after that. In addition, the affixing layer 27 may be formed by applying an affixing agent having fluidity such as a liquid, or may also be formed by using a sheet-like affixing agent.

Here, for example, the vibration element 14 is an exciter, and the vibration element 14 is stretched and contracted by stretching and contracting the plurality of the laminated layers of the piezoelectric film 24, thereby vibrating the vibration plate 12 which will be described later to output a voice. Accordingly, in the vibration element 14, it is preferable that the stretching and contraction of each piezoelectric film 24 is directly transmitted. In a case where a substance having a viscosity to relieve vibration is present between the layers of the piezoelectric film 24, the efficiency of transmitting the stretching and contracting energy of the piezoelectric film 24 is lowered, and thus, the driving efficiency of the vibration element 14 decreases.

In consideration of this point, the affixing layer 27 is preferably an adhesive layer consisting of an adhesive with which a solid and hard affixing layer 27 is obtained, rather than a pressure sensitive adhesive layer consisting of a pressure sensitive adhesive. Specific suitable examples of a more preferred affixing layer 27 include an affixing layer consisting of a thermoplastic type adhesive such as a polyester-based adhesive and a styrene-butadiene rubber (SBR)-based adhesive.

Adhesion, which is different from pressure sensitive adhesion, is useful in a case where a high adhesion temperature is required. In addition, the thermoplastic type adhesive has characteristics of “a relatively low temperature, a short time, and strong adhesion”, which is thus suitable.

In the vibration element 14, the thickness of the affixing layer 27 is not limited, and a thickness capable of exhibiting sufficient affixing force may be appropriately set according to a material for forming the affixing layer 27.

Here, in the vibration element 14, the thinner the affixing layer 27, the higher the effect of transmitting the stretching and contracting energy (vibration energy) of the piezoelectric layer 26, and the higher the energy efficiency. In addition, in a case where the affixing layer 27 is thick and has high rigidity, there is a possibility that the stretching and contraction of the piezoelectric film 24 may be constrained.

In consideration of this point, it is preferable that the affixing layer 27 is thinner than the piezoelectric layer 26. That is, it is preferable that the affixing layer 27 in the vibration element 14 is hard and thin. Specifically, the thickness of the affixing layer 27 is preferably in a range of 0.1 to 50 μm, more preferably in a range of 0.1 to 30 μm, and still more preferably in a range of 0.1 to 10 μm in terms of thickness after affixing.

Furthermore, in the vibration element 14 constituting the electroacoustic transducer 10 of the embodiment of the present invention, the affixing layer 27 is provided in a preferred embodiment, and is not an essential constituent element.

However, in a case where the affixing layer 27 is not provided, each piezoelectric film 24 is bent in the opposite direction to form voids, which may reduce a driving efficiency of the piezoelectric element.

In consideration of this point, in a case where the piezoelectric element constituting the electroacoustic transducer of the embodiment of the present invention is configured by laminating a plurality of layers of the piezoelectric film 24, the piezoelectric element preferably has an affixing layer 27 that affixes the adjacent layers of the piezoelectric film 24 to each other by the vibration element 14 in the example illustrated in the figure.

Moreover, in the electroacoustic transducer of the embodiment of the present invention, the piezoelectric element is not limited to one having a plurality of layers of the piezoelectric film 24 laminated by folding the piezoelectric film 24.

For example, the piezoelectric element may be one in which a plurality of cut sheet-like piezoelectric films 24 are laminated, and preferably, the adjacent piezoelectric films are affixed to each other by the affixing layer 27. At this time, the number of laminated layers is not limited, which is the same as that of the vibration element 14 in which layers of the piezoelectric film 24 are laminated by folding the piezoelectric film 24. In addition, in a case where a plurality of cut sheet-like piezoelectric films 24 are laminated to form a piezoelectric element, a configuration in which different piezoelectric films are laminated to form a piezoelectric element, such as a configuration in which a piezoelectric film 24 having a protective layer and a piezoelectric film having no protective layer are laminated, may be used.

Alternatively, the piezoelectric element may be one composed of one sheet of the piezoelectric film 24 as long as a sufficient stretching and contracting force can be obtained for vibration of the vibration plate 12.

A first extraction electrode 24a and a second extraction electrode 24b for electrically connecting to an external device such as a power supply device are connected to the piezoelectric film 24 of the vibration element 14. A wiring line 25a connected to an external device is connected to the first extraction electrode 24a, and a wiring line 25b connected to the external device is connected to the second extraction electrode 24b.

The first extraction electrode 24a is an electrode electrically extracted from the first electrode layer 28, and the second extraction electrode 24b is an electrode electrically extracted from the second electrode layer 30. In the following description, in a case where it is not necessary to distinguish between the first extraction electrode 24a and the second extraction electrode 24b, the both extraction electrodes are also simply referred to as an extraction electrode.

In the electroacoustic transducer 10 of the embodiment of the present invention, the connection method between the electrode layer and the extraction electrode is not limited, and various methods can be used.

In the illustrated example, as an example, a sheet-like extraction electrode is inserted between the electrode layer and the piezoelectric layer, and a wiring line is connected to the extraction electrode. Furthermore, the extraction electrode may be inserted between the electrode layer and the protective layer.

As another example of the connection method, a method in which a through-hole is formed in a protective layer, an electrode connecting member formed of a metal paste such as a silver paste is provided so as to fill the through-hole, and an extraction electrode is provided in the electrode connecting member is exemplified. Alternatively, the wiring line may be inserted directly between the electrode layer and the piezoelectric layer, or between the electrode layer and the protective layer, and the extraction electrode may be connected to the electrode layer. Still other examples of the connection method include a method in which a part of a protective layer and an electrode layer is projected from a piezoelectric layer in the plane direction, and an extraction electrode is connected to the projected electrode layer. Furthermore, the extraction electrode and the electrode layer may be connected by a known method such as a method using a metal paste such as a silver paste, a method using a solder, and a method using a conductive adhesive.

Suitable examples of the method for extracting an electrode include the method described in JP2014-209724A and the method described in JP2016-015354A.

Such a vibration element 14 is affixed to the vibration plate 12 by an affixing layer (not shown).

In the present invention, as the affixing layer, various known affixing layers can be used as long as the vibration plate 12 and the vibration element 14 (piezoelectric film 24) can be affixed to each other.

Therefore, the affixing layer may be the layer consisting of an adhesive, the layer consisting of a pressure sensitive adhesive, or the layer consisting of a material having characteristics of both an adhesive and a pressure sensitive adhesive, each mentioned above. In addition, the affixing layer may be formed by applying an affixing agent having fluidity such as a liquid, or may also be formed by using a sheet-like affixing agent.

Here, in the electroacoustic transducer 10 of the embodiment of the present invention, the vibration element 14 is stretched and contracted by stretching and contracting a plurality of laminated layers of the piezoelectric film 24, and the vibration plate 12 is bent and vibrates by the stretching and contraction of the vibration element 14, thereby outputting a voice. Accordingly, in the electroacoustic transducer 10 of the embodiment of the present invention, it is preferable that the stretching and contraction of the vibration element 14 is directly transmitted to the vibration plate 12. In a case where a substance having a viscosity that relieves vibration is present between the vibration plate 12 and the vibration element 14, the efficiency of transmitting the stretching and contracting energy of the vibration element 14 to the vibration plate 12 is lowered, and thus, the driving efficiency of the electroacoustic transducer 10 decreases.

In consideration of this point, the affixing layer is preferably an adhesive layer consisting of an adhesive, with which a hard affixing layer that is a solid is obtained, rather than a pressure sensitive adhesive layer consisting of a pressure sensitive adhesive. Specific suitable examples of a more preferred affixing layer include an affixing layer consisting of a thermoplastic type adhesive such as a polyester-based adhesive and a styrene-butadiene rubber (SBR)-based adhesive.

Adhesion, which is different from pressure sensitive adhesion, is useful in a case where a high adhesion temperature is required. In addition, the thermoplastic type adhesive has characteristics of “a relatively low temperature, a short time, and strong adhesion”, which is thus suitable.

In the electroacoustic transducer 10 of the embodiment of the present invention, the thickness of the affixing layer to which the vibration plate 12 and the vibration element 14 are affixed is not limited, and a thickness capable of exhibiting a sufficient affixing force may be appropriately set according to a material for forming the affixing layer 27.

Here, in the electroacoustic transducer 10 in the example illustrated in the figure, the thinner the affixing layer, the higher the effect of transmitting the stretching and contracting energy (vibration energy) of the piezoelectric layer 26, and the higher the energy efficiency. In addition, in a case where the affixing layer is thick and has high rigidity, there is a possibility that the stretching and contraction of the vibration element 14 may be constrained.

In consideration of this point, it is preferable that the affixing layer is thin.

Specifically, the thickness of the affixing layer to which the vibration plate 12 and the vibration element 14 are affixed is preferably in a range of 10 to 1,000 μm, more preferably 30 to 500 μm, and still more preferably 50 to 300 μm in terms of the thickness after the affixing.

In the electroacoustic transducer 10 in the example illustrated in the figure, the piezoelectric film 24 is formed by interposing the piezoelectric layer 26 between the first electrode layer 28 and the second electrode layer 30.

The piezoelectric layer 26 preferably has the piezoelectric particles 40 in the polymer matrix 38. Preferably, in the piezoelectric layer 26, the piezoelectric particles 40 are dispersed in the polymer matrix 38.

In a case where a voltage is applied to the second electrode layer 30 and the first electrode layer 28 of the piezoelectric film 24 having such a piezoelectric layer 26, the piezoelectric particles 40 stretch and contract in the polarization direction according to the applied voltage. As a result, the piezoelectric film 24 (piezoelectric layer 26) contracts in the thickness direction. At the same time, the piezoelectric film 24 stretches and contracts in the plane direction due to the Poisson's ratio.

The degree of stretching and contraction is approximately in a range of 0.01% to 0.1%. As described above, a thickness of the piezoelectric layer 26 is preferably approximately 10 to 300 μm. Accordingly, the degree of stretching and contraction in the thickness direction is as extremely small as approximately 0.3 μm at most.

On the contrary, the piezoelectric film 24, that is, the piezoelectric layer 26, has a size much larger than the thickness in the plane direction. Accordingly, for example, in a case where the length of the piezoelectric film 24 is 20 cm, the piezoelectric film 24 stretches and contracts by about 0.2 mm at most by the application of a voltage.

As mentioned above, the vibration element 14 has five layers of the piezoelectric film 24 laminated by folding the piezoelectric film 24 back. In addition, the vibration element 14 is affixed to the vibration plate 12 by the affixing layer.

The vibration element 14 also stretches and contracts in the same direction by the stretching and contraction of the piezoelectric film 24. The stretching and contraction of the vibration element 14 causes the vibration plate 12 to bend, and as a result, the vibration plate 12 vibrates in the thickness direction.

The vibration plate 12 outputs a voice due to the vibration in the thickness direction. That is, the vibration plate 12 vibrates according to the magnitude of the voltage (driving voltage) applied to the piezoelectric film 24 to output a voice according to the driving voltage applied to the piezoelectric film 24.

As mentioned above, the vibration element 14 in the example illustrated in the figure has five layers of such a piezoelectric film 24 laminated. In the vibration element 14 in the example illustrated in the figure, as a preferable embodiment, the layers of the piezoelectric film 24 adjacent to each other are further affixed by the affixing layer 27.

Therefore, even though the rigidity of each sheet of the piezoelectric film 24 is low and the stretching and contracting force thereof is small, the rigidity is increased by laminating the layers of the piezoelectric film 24, and the stretching and contracting force as the vibration element 14 is increased. As a result, in the vibration element 14, even in a case where the vibration plate 12 has a certain degree of rigidity, the vibration plate 12 can be sufficiently bent with a large force, and the vibration plate 12 can thus sufficiently vibrate in the thickness direction to output a voice with the vibration plate 12.

Moreover, as mentioned above, in the piezoelectric film 24 constituting the vibration element 14, the thickness of the piezoelectric layer 26 is preferably about 300 μm at the maximum. Further, the piezoelectric film 24 using the piezoelectric layer 26, which is a polymer-based piezoelectric composite material, has very good flexibility.

Therefore, the vibration element 14 is very thin and has good flexibility even in a case where a plurality of layers (five layers in the illustrated example) of the piezoelectric film 24 are laminated. Accordingly, by using the vibration element 14 with such a piezoelectric film 24, the vibration element 14 suitably follows the rolling-up of the vibration plate 12 in a case where the vibration plate 12 is rolled up. As a result, the electroacoustic transducer 10 provided with the vibration element 14 using the piezoelectric film 24 can suitably perform the rolling-up.

As shown in FIG. 1, in the electroacoustic transducer 10, a convex leaf spring 16 is provided on a surface of the vibration plate 12 to which the vibration element 14 is affixed.

The convex leaf spring is a strip-shaped leaf spring which is generally formed of a metal material such as stainless steel and has an arc-shaped (bow-shaped) cross section in a lateral direction. In other words, the convex leaf spring is a leaf spring having a rain gutter shape. In the electroacoustic transducer of the embodiment of the present invention, the convex leaf spring 16 has a concave side disposed facing the vibration plate 12. That is, the convex side of the convex leaf spring 16 is opposite to the vibration plate 12.

The convex leaf spring maintains a straight strip shape, that is, a long plate shape having an arc shape in the lateral direction in a state where the convex leaf spring has an arc-shaped cross section. In addition, in a case where the convex leaf spring forms a flat plate-shaped (substantially flat plate-shaped) cross section in the lateral direction by crushing an arc, that is, pressing the convex side, it forms a curled state in the longitudinal direction or a circular arc shape in the longitudinal direction. Further, in a case where the convex leaf spring expands in a band shape from the curled state, it forms an arc-shaped cross section in the lateral direction, and returns to the straight strip-shaped cross section again.

That is, the convex leaf spring is a plate-like spring member that reversibly deforms between a strip-shaped state having an arc-shaped cross section in the lateral direction and a rounded state having a flat plate-shaped cross section in a lateral direction.

In the electroacoustic transducer 10 (image display device) of the embodiment of the present invention, such the convex leaf spring 16 is combined with the rollable vibration plate 12 (rollable display element). The electroacoustic transducer 10 according to the embodiment of the present invention realizes both of maintaining the vibration plate 12 to be in a flat plate shape during use and enabling the vibration plate 12 to be rolled up during non-use and the like. Moreover, the electroacoustic transducer 10 according to the embodiment of the present invention does not need a complicated mechanical mechanism and a driving source to enable the maintenance of the flat plate shape and enables the rolling-up, and can further have a reduced weight.

That is, in a case where the electroacoustic transducer 10 is used as a speaker or the like, that is, at the time of outputting a voice, the vibration plate 12 is supported by the strip-shaped convex leaf spring 16 and maintained to be planar, as conceptually shown in FIGS. 1 and 8.

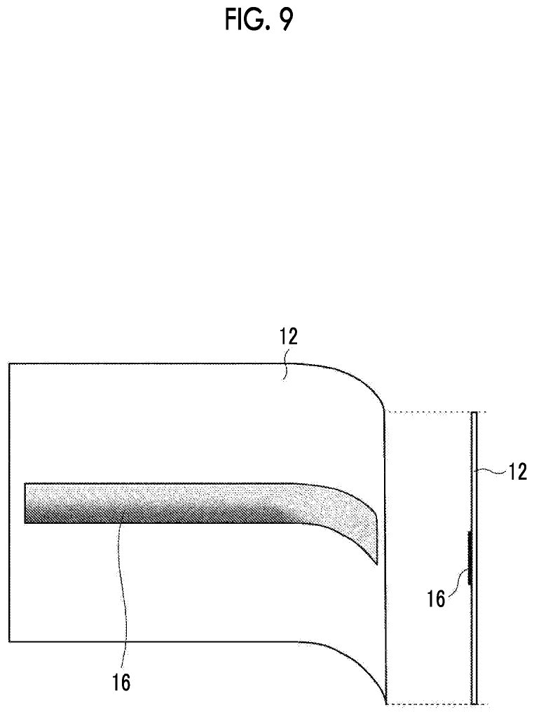

On the other hand, in a case where the vibration plate 12, that is, the electroacoustic transducer 10 is rolled up, the convex part of the convex leaf spring 16 is pressed toward the vibration plate 12, and a part or the entire area of the convex leaf spring 16 forms a planar shape, as conceptually shown in FIG. 9. As mentioned above, in the flat plate shape, the convex leaf spring 16 is brought into a state of being curled in the longitudinal direction by its own biasing force. Therefore, in this state, the support by the convex leaf spring 16 is lost, and as shown in FIG. 9, the vibration plate 12 can be rolled up in the longitudinal direction of the convex leaf spring 16.

Furthermore, in FIG. 8 and FIG. 9, the vibration element 14 and the like are omitted in order to simplify the drawings.

In addition, the convex leaf spring 16 has an arc-shaped cross section. That is, the convex leaf spring 16 has a rain gutter shape. Further, in the present invention, the convex leaf spring 16 has a concave side disposed facing the vibration plate 12. That is, a space is formed between the convex leaf spring 16 and the vibration plate 12 by the arc of the convex leaf spring 16.

Therefore, in the electroacoustic transducer 10 of the embodiment of the present invention, the wiring line 25a and the wiring line 25b for connecting one of the vibration elements 14 and the external device can be passed through the convex leaf spring 16 to be combined with the wiring line 25a and the wiring line 25b connected to the other of the vibration elements 14, as shown in FIG. 1. That is, according to the electroacoustic transducer 10 of the embodiment of the present invention, it is possible to concisely arrange the wiring lines.

In the electroacoustic transducer 10 of the embodiment of the present invention, the vibration plate 12 may be automatically curled by pressing the convex part of the convex leaf spring 16. Alternatively, in the electroacoustic transducer 10 according to the embodiment of the present invention, in a state where the convex part of the convex leaf spring 16 is pressed, the vibration plate 12 can be rolled up, but may be in a state of being maintained in a flat plate shape.

These can be selectively realized by adjusting and/or selecting a biasing force of the convex leaf spring 16 to be curled and a rigidity of the vibration plate 12. The rigidity of the vibration plate 12 is a so-called strength of stiffness of the sheet-like material.

That is, in a case where the biasing force, that is, the biasing force of the convex leaf spring 16 at the time of flattening the convex by pressing is sufficiently strong with respect to the rigidity of the vibration plate 12, the vibration plate 12 can be automatically curled by pressing a part of the convex part of the convex leaf spring 16.

On the other hand, in a case where the rigidity of the vibration plate 12 is high with respect to the biasing force of the convex leaf spring 16, the vibration plate 12 is not automatically curled and the vibration plate 12 can be manually brought into a rollable state even in a case where the convex part of the convex leaf spring 16 is pressed.

At this time, by adjusting a balance between the biasing force of the convex leaf spring 16 and the rigidity of the vibration plate 12, the entire area of the vibration plate 12 may be rollable by a partial pressing of the convex leaf spring 16. Alternatively, by adjusting a balance between the biasing force of the convex leaf spring 16 and the rigidity of the vibration plate 12, only the pressing part of the convex leaf spring 16 may be rollable.

In this configuration, the vibration plate 12 is brought into a state of being partially bent to an arbitrary curvature and the other areas are maintained in a flat plate shape, whereby the electroacoustic transducer 10 can be used as a speaker or the like in an upright state.

As shown in FIG. 1, in a case where the wiring line 25a and the wiring line 25b are passed through a concave part of the convex leaf spring 16, an adjustment between the biasing force of the convex leaf spring 16 and the rigidity of the vibration plate 12 can be performed by adjusting (selecting) the thickness of the wiring line.

That is, in a case where the wiring line is thin, the convex leaf spring 16 can be formed into a flat plate shape by pressing the convex. At this time, by crushing the convex leaf spring 16 into a flat plate shape, the convex leaf spring 16 exerts the original biasing force for curling.

In contrast, in a case where the wiring line is thick, the convex leaf spring 16 cannot be formed into a flat plate shape even in case where the convex is pressed. At this time, the convex leaf spring 16 cannot exert the original biasing force for curling. That is, in a case where the wiring line is thick, the biasing force of the convex leaf spring 16 can be reduced in a pseudo manner.

Accordingly, in a case where the wiring line 25a and the wiring line 25b are passed through the concave part of the convex leaf spring 16, by selecting the thickness of the wiring line, it is possible to selectively set a state where the entire area of the vibration plate 12 can be rolled up while the vibration plate 12 is automatically rolled up and maintained in the form of a flat plate in a case where the convex part of the convex leaf spring 16 is pressed, and a state where only the pressing part of the convex leaf spring 16 can be rolled up.

The convex leaf spring 16 is not limited as long as it is a spring member that elastically deforms between a strip-shaped state where the cross section in the lateral direction is in an arc shape, and a state where the cross section in the lateral direction is flattened and curled, and a variety of known convex leaf springs can be used. Furthermore, the convex leaf spring is also referred to as a convex spring, a convex metal shard, a convex member, a convex metal member, a convex conston, or the like.

In addition, a material for forming the convex leaf spring 16 is not limited to the above-mentioned metal material such as stainless steel.

In the electroacoustic transducer 10 shown in FIG. 1, the convex leaf spring 16 is provided at the center of the vibration plate 12 in the short side direction with the longitudinal direction being in parallel to the long side of the rectangular vibration plate 12.

However, in the electroacoustic transducer 10 of the embodiment of the present invention, the arrangement position of the convex leaf spring 16 is not limited to this position. That is, the position of the convex leaf spring 16 may be appropriately set according to a size of the vibration plate 12, a shape of the vibration plate 12, a desired rolling direction of the vibration plate 12, a range within which a user's finger can reach so that the user can easily crush into a flat plate, a position of the vibration element 14, and the like.

In addition, in the electroacoustic transducer 10 of the embodiment of the present invention, basically only one convex leaf spring 16 is provided. However, the electroacoustic transducer of the embodiment of the present invention is not limited thereto, and may have a plurality of convex leaf springs 16 as necessary.

For example, a configuration in which a convex leaf spring along the long side is provided in the vicinity of an end part in the short side direction corresponding to two adjacent sides of the rectangular vibration plate 12, and a convex leaf spring along the short side is provided in the vicinity of an end part in the long side direction is exemplified. According to this configuration, the rolling-up along the long side and the rolling-up along the short side, that is, the rolling-up of the vibration plate 12 in the X and Y directions orthogonal to each other can be achieved.

A method for attaching the convex leaf spring 16 is not limited, and a known method is available, depending on materials for forming the convex leaf spring 16 and a mounting position of the convex leaf spring 16, that is, materials for forming the vibration plate 12 and the vibration element 14 in the illustrated example.

In an example, a method of affixing an end part of the arc of the cross section of the convex leaf spring 16 in the lateral direction and the abutting part with the vibration plate 12 or the like, using an affixing agent, a double-sided tape, or the like, is exemplified. The end part of the arc of the cross section of the convex leaf spring 16 in the lateral direction is, in other words, two linear portions extending in the longitudinal direction on a release side of the concave.

For the affixing, the above-mentioned adhesive or pressure sensitive adhesive may also be used.

Here, in a state where the convex part of the convex leaf spring 16 is pressed to flatten the convex leaf spring 16, the convex leaf spring 16 slightly expands in the lateral direction.

Since the expanding part of the convex leaf spring 16 in a case of being flattened by pressing is very small, it can often be absorbed by the elasticity of the vibration plate 12.

Alternatively, the expanding part of the convex leaf spring 16 in a case where the convex is pressed and flattened may be absorbed by affixing the convex leaf spring 16 to the vibration plate 12 and the like with a stretchable material. Examples of the stretchable adhesive material include an elastic affixing agent, an elastic double-sided tape, a rubber-like affixing agent, and a rubber-like double-sided tape.

As described above, the vibration element 14 is formed by folding back and laminating a thin piezoelectric film 24 in which an electrode layer and a protective layer are provided on both surfaces of the piezoelectric layer 26, and is conducted. It is not preferable that such a vibration element 14 can be brought into contact from the outside.

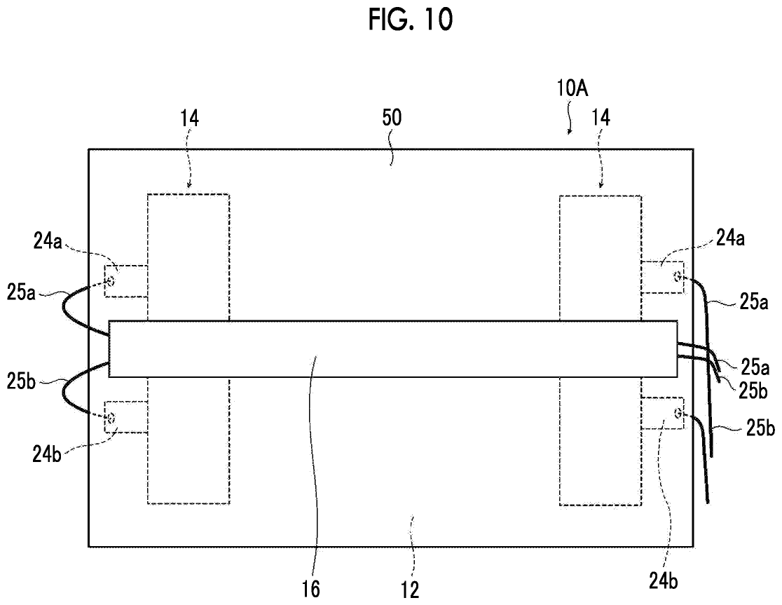

Accordingly, in the electroacoustic transducer of the embodiment of the present invention, it is preferable that the vibration element 14 is covered on a surface of the vibration plate 12, onto which the vibration element 14 is affixed, to provide a protective sheet 50 on the entire surface, as in an electroacoustic transducer 10A conceptually shown in FIG. 10. The protective sheet 50 is a cover member according to the present invention. Furthermore, in a case where the protective sheet 50 that covers the vibration element 14 is provided, the convex leaf spring 16 is affixed onto the protective sheet 50, for example, as mentioned above.

As a result, the safety of a user with the electroacoustic transducer 10 can be secured, and the vibration element 14 can be protected to prolong the life of the electroacoustic transducer 10. Further, the color and the like of the protective sheet 50 can also be selected as necessary to improve the designability of the electroacoustic transducer 10.

Furthermore, the protective sheet 50 may be provided so as to cover only the vibration element 14, but it is preferable that the protective sheet 50 is provided on the entire surface of the vibration plate 12 as shown in FIG. 10 in consideration of designability and the like.

In addition, the convex leaf spring 16 is not limited to be provided on a surface of the protective sheet 50. That is, as in the example shown in FIG. 1, the protective sheet 50 may be provided by affixing the convex leaf spring 16 to the vibration plate 12 and the like to cover the convex leaf spring 16. However, in the present invention, the convex leaf spring 16 is preferably provided on the surface of the protective sheet 50. In addition, after the convex leaf spring 16 is provided on the surface of the protective sheet 50, a second protective sheet may be provided to cover the convex leaf spring 16.

The material for forming the protective sheet 50 is not limited, and various sheet-like materials can be used as long as they can cover and protect the vibration element 14.

In an example, various sheet-like materials such as a resin film, which are exemplified as the vibration plate 12 mentioned above, are exemplified, but the protective sheet 50 may have innumerable irregularities formed on a surface thereof so as to have high heat dissipation and a material having excellent thermal conductivity, such as a metal, may also be used.

The thickness of the protective sheet 50 is also not limited, and a thickness that can protect the vibration element 14 and does not impair the flexibility of the vibration plate 12 may be appropriately set according to a material for forming the protective sheet 50. The thickness of the protective sheet 50 is preferably 10 to 300 μm, and more preferably 30 to 100 μm.

Here, the vibration element 14 on which the piezoelectric film 24 is laminated is thin as mentioned above, but naturally has a thickness.

Therefore, in a case where the vibration plate 12 is covered with the protective sheet 50, a level difference is generated in the protective sheet 50 according to the thickness of the vibration element 14. In a case where the protective sheet 50 has the level difference, inconveniences such that an adhesive force of the convex leaf spring 16 to the protective sheet 50 is lowered and a contact state between the convex leaf spring 16 and the vibration plate 12 through the protective sheet 50 is deteriorated may occur.

In order to avoid such inconveniences, it is preferable that the thickness of the protective sheet 50 of the portion that does not come into contact with the vibration element 14 is increased in accordance with the thickness of the vibration element 14, and the surface of the protective sheet 50 is a flattened surface (a substantially flat surface) without a level difference.

In addition, the protective sheet 50 may be provided with a counterbore corresponding to the thickness of the vibration element 14 to eliminate the level difference. Further, in a case where the protective sheet 50 is made of a material having a low resilience such as urethane, it is possible to install the convex leaf spring 16 on a surface of the protective sheet 50 after absorbing unevenness due to the thickness of the vibration element to form a flat surface.

Furthermore, it should be noted that such inconveniences caused by the thickness of the vibration element 14 are also the same in the electroacoustic transducer 10 which does not have the protective sheet 50 as shown in FIG. 1.

Therefore, in the electroacoustic transducer 10 shown in FIG. 1, a level difference eliminating sheet having the same thickness (substantially the same thickness) as that of the vibration element 14 is provided in a region of the vibration plate 12 where the vibration element 14 does not exist to eliminate the level difference, and the convex leaf spring 16 may be provided on the level difference eliminating sheet and the vibration element 14 as mentioned above. Furthermore, the level difference eliminating sheet may be provided on the entire surface of a region of the vibration plate 12 other than the vibration element 14, or may be provided only at a position at which the convex leaf spring 16 is arranged.

Alternatively, the convex leaf spring 16 may also be affixed on the protective sheet 50 having a uniform thickness, as mentioned above, after the same level difference eliminating sheet is provided in a region of the vibration plate 12 where the vibration element 14 does not exist, and the protective sheet 50 is provided on the level difference eliminating sheet and the vibration element 14.

As the level difference eliminating sheet, the same sheet as the protective sheet 50 is available.

In the electroacoustic transducer of the embodiment of the present invention, the problem with a level difference due to the thickness of the vibration element 14 at the position at which the convex leaf spring 16 is installed may be solved by setting the positions at which the vibration element 14 and the convex leaf spring 16 are installed to different positions of the vibration plate 12 in the plane direction.

In an example, the vibration elements 14 may be provided at the four corners of the rectangular vibration plate 12. As a result, it is possible to respond to stereo reproduction as in the electroacoustic transducer 10 shown in FIG. 1, and at the same time, it is possible to solve the problem of a level difference due to the thickness of the vibration element 14 by setting the positions at which the vibration element 14 and the convex leaf spring 16 are installed to different positions in the vibration plate 12.

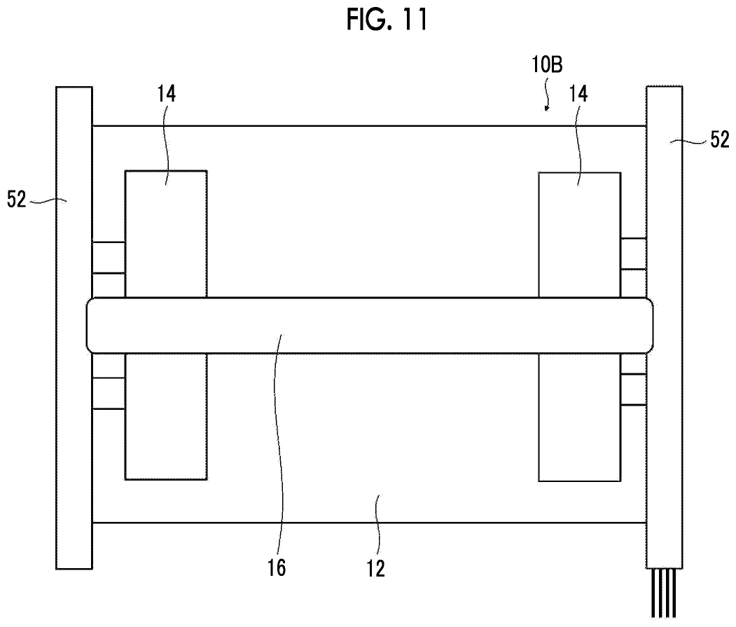

FIG. 11 conceptually shows another example of the electroacoustic transducer of the embodiment of the present invention.

In the electroacoustic transducer 10B shown in FIG. 11, the electroacoustic transducer 10 described above is further provided with a tubular member 52. Furthermore, it should be noted that the tubular member 52 shown below can be used in the same manner in an aspect in which the protective sheet 50 is provided as shown in FIG. 10.

The tubular member 52 is suitably used in a case where the vibration plate 12 is rectangular.

In the electroacoustic transducer 10B, the convex leaf spring 16 is provided in parallel to one side of the rectangular vibration plate 12 or the long side in the illustrated example. That is, in the illustrated example, the long side of the vibration plate 12 and the longitudinal direction of the convex leaf spring 16 are in parallel to each other.

The tubular member 52 is provided corresponding to both end parts (both end sides) in a direction orthogonal to the longitudinal direction of the convex leaf spring 16 in the rectangular vibration plate 12.

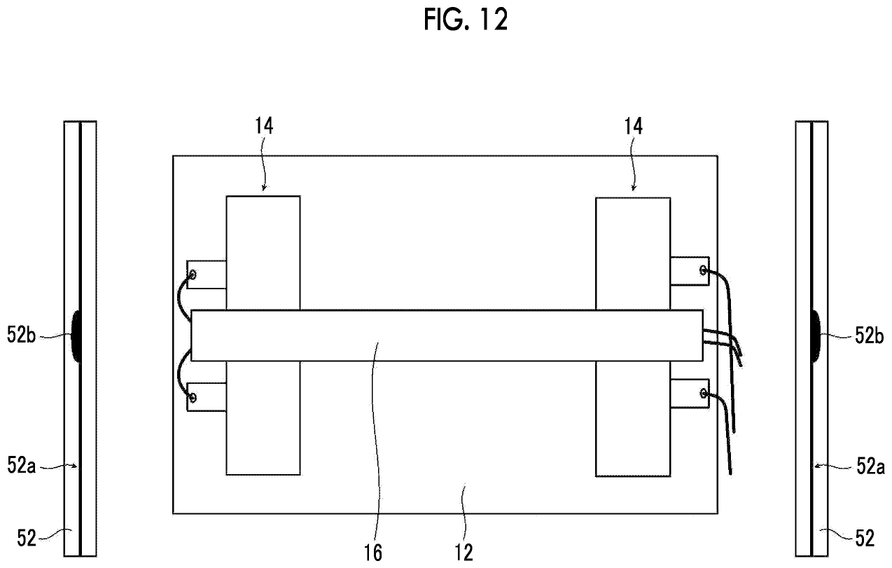

As conceptually shown in FIG. 12, the tubular member 52 is cylindrical as an example and has a linear notch 52a on the side surface that coincides with the direction of the central axis. The tubular member 52 is provided by inserting an end part of the vibration plate 12 that is orthogonal to the convex leaf spring 16 in the longitudinal direction into the notch 52a.

As mentioned above, the electroacoustic transducer according to the embodiment of the present invention makes it possible to maintain the flatness of the vibration plate 12 and to roll the vibration plate 12 up during non-use and the like without a complicated mechanical mechanism and a driving source by inclusion of the convex leaf spring 16.

An electroacoustic transducer 10B of an embodiment of the present invention further has a tubular member 52, in addition to the convex leaf spring 16. Accordingly, the flatness in a direction orthogonal to the longitudinal direction of the convex leaf spring 16, that is, the short side direction of the vibration plate 12 can also be more suitably maintained, in addition to that in the longitudinal direction of the convex leaf spring 16, that is, the long side direction of the vibration plate 12. Furthermore, since the rolling direction of the vibration plate in the electroacoustic transducer according to the present invention is the longitudinal direction of the convex leaf spring 16, the tubular member 52 does not interfere with the rolling-up of the vibration plate 12.

In addition, the tubular member 52 also serves as a gripping part for holding the electroacoustic transducer 10B without coming into contact with the vibration plate 12. Further, depending on the shape, the tubular member 52 can also be used as a stand for standing the electroacoustic transducer 10B.

Moreover, in the electroacoustic transducer 10B, the tubular member 52 preferably has an insertion part 52b having a slightly wider width at a position of the notch 52a, corresponding to the convex leaf spring 16. As shown in FIG. 11, the convex leaf spring 16 is inserted into the insertion part 52b at an end part in the longitudinal direction.

By configuring the tubular member 52 to have such an insertion part 52b and have the end part of the convex leaf spring 16 inserted thereinto, the wiring line 25a and the wiring line 25b of one of the vibration elements 14 can be passed from one of tubular members 52 to the other tubular member 52 through the convex leaf spring 16. In addition, the wiring line 25a and the wiring line 25b of the other vibration element 14 can also be passed through the tubular member 52.

As a result, according to the electroacoustic transducer 10B, the wiring lines 25a and the wiring lines 25b connected to the vibration element 14 can be more preferably combined, and the wire routings can be arranged more concisely.

Further, the convex leaf spring 16 can be supported by the tubular member 52 by incorporating the insertion part 52b into the tubular member 52, and inserting the end part of the convex leaf spring 16.

Therefore, with this configuration, it no longer needs to necessarily affix the convex leaf spring 16 to the vibration plate 12 and the like. As a result, it is possible to more easily perform flattening by pressing the convex part of the convex leaf spring 16 in a case of rolling up the film from the vibration plate 12.

Furthermore, the tubular member 52 is not limited to a cylindrical shape, and various shapes can be used as long as they are any of a tubular shape, for example, an angular tubular shape such as a triangular tubular shape and a rectangular tubular shape, and an elliptical tubular shape.

In addition, in the example shown in FIG. 11, the tubular member 52 is provided at both end parts of the vibration plate 12 in a direction orthogonal to the longitudinal direction of the convex leaf spring 16, but the present invention is not limited thereto, and the tubular member 52 may be provided on only one of the end parts. However, from the viewpoint that the flatness of the vibration plate 12 can be more suitably secured, it is preferable that the tubular member 52 is provided at both end parts of the vibration plate 12 in a direction orthogonal to the longitudinal direction of the convex leaf spring 16.

In the electroacoustic transducer of the embodiment of the present invention described above, the rollable image display device of the embodiment of the present invention is provided with a rollable display element (a display device or a display panel) instead of the vibration plate. In the following description, the “rollable image display device” is also simply referred to as an “image display device”. In the image display device according to the embodiment of the present invention, the display element which can be rolled up is not limited, and various known display elements can be used as long as the display elements have flexibility that allow rolling-up. In an example, a display element that can be used as the above-mentioned vibration plate 12 is exemplified.

In the image display device of the embodiment of the present invention, the above-mentioned vibration element 14 is not an essential configuration requirements but is provided as a preferable aspect. Accordingly, in the image display device of the embodiment of the present invention, a speaker and the like may be separately connected for an audio output.

In addition, in the image display device of the embodiment of the present invention, the convex leaf spring 16 and the vibration element 14 are arranged on a surface of the display element opposite to the image display surface.

The image display device of the embodiment of the present invention basically has the same configuration as the above-mentioned electroacoustic transducer of the embodiment of the present invention, except that those points are different.

While the rollable electroacoustic transducer and the rollable image display device of the embodiments of the present invention have been described in detail, the present invention is not limited to the above-mentioned examples, and various improvements or modifications may be naturally performed within a range not deviating from the gist of the present invention.

The electroacoustic transducer and the image display device can be suitably used as a speaker, an image display device, and the like in various applications.

### EXPLANATION OF REFERENCES

10, 10A, 10B: electroacoustic transducer
12: vibration plate
14: vibration element
16: convex leaf spring
24: piezoelectric film
24a: first extraction electrode
24b: second extraction electrode
26: piezoelectric layer
28: first electrode layer
30: second electrode layer
32: first protective layer
34: second protective layer
38: polymer matrix
40: piezoelectric particles
42a, 42b: laminate
46: piezoelectric laminate
50: protective sheet
52: tubular member
52a: notch
52b: insertion part

What is claimed is:

1. A rollable electroacoustic transducer comprising:
a rollable vibration plate;
a vibration element that causes the vibration plate to violate; and
a convex leaf spring having an arc-shaped cross section in a lateral direction thereof and having a concave side disposed facing one main surface of the vibration plate.

2. The rollable electroacoustic transducer according to claim 1,
wherein a wiring line for driving the vibration element is inserted between the convex leaf spring and the vibration plate.

3. The rollable electroacoustic transducer according to claim 1,
wherein the vibration plate has a rectangular shape and the convex leaf spring is provided with a longitudinal direction thereof being in parallel to one side of the vibration plate, and
the rollable electroacoustic transducer further has a tubular member in a slit formed on a side surface thereof, in which an end part of the vibration plate in a direction orthogonal to the longitudinal direction of the convex leaf spring is inserted into the tubular member and the tubular member extends in the same direction as the end part.

4. The rollable electroacoustic transducer according to claim 3,
wherein an end part in the longitudinal direction of the convex leaf spring is inserted into the tubular member.

5. The rollable electroacoustic transducer as described according to claim 1,
wherein the rollable electroacoustic transducer has a cover member that covers the vibration element, and the vibration plate, the vibration element, the cover member, and the convex leaf spring are disposed in this order in a direction orthogonal to a main surface of the vibration plate.

6. The rollable electroacoustic transducer according to claim 1,
wherein the vibration plate is a display element or a projection screen.

7. The rollable electroacoustic transducer according to claim 1,
wherein the vibration element has a laminate where a plurality of layers of a piezoelectric film including a piezoelectric layer, electrode layers provided on both sides of the piezoelectric layer, and protective layers covering the electrode layers are laminated.

8. The rollable electroacoustic transducer according to claim 7,
wherein the piezoelectric layer of the piezoelectric film is a polymer-based piezoelectric composite material having piezoelectric particles in a polymer material.

9. The rollable electroacoustic transducer according to claim 8,
wherein the polymer material of the polymer-based piezoelectric composite material is cyanoethylated polyvinyl alcohol.

10. A rollable image display device comprising:
a rollable display element; and
a convex leaf spring having an arc-shaped cross section in a lateral direction thereof and having a concave surface disposed facing a non-image-displaying surface of the display element, the convex leaf spring being provided on the non-image-displaying surface side of the display element.

11. The rollable image display device according to claim 10,
wherein the convex leaf spring is provided with a longitudinal direction thereof being in parallel to one side of the display element, and
the rollable image display device further has a tubular member in a slit formed on a side surface thereof, in which an end part of the display element in a direction orthogonal to the longitudinal direction of the convex leaf spring is inserted into the tubular member and the tubular member extends in the same direction as the end part.

12. The rollable image display device according to claim 11,
wherein an end part in the longitudinal direction of the convex leaf spring is inserted into the tubular member.

13. The rollable image display device according to claim 10, further comprising a vibration element that vibrates the display element, the vibration element being provided on a non-image-displaying surface side of the display element.

14. The rollable image display device according to claim 13,
wherein a wiring line for driving the vibration element is inserted between the convex leaf spring and the display element.

15. The rollable image display device according to claim 13,
wherein the rollable image display device has a cover member that covers the vibration element, and the display element, the vibration element, the cover member, and the convex leaf spring are disposed in this order in a direction orthogonal to an image display surface of the display element.

16. The rollable image display device according to claim 13,
wherein the vibration element has a laminate where a plurality of layers of a piezoelectric film including a piezoelectric layer, electrode layers provided on both sides of the piezoelectric layer, and protective layers covering the electrode layers are laminated.

17. The rollable image display device according to claim 16,
wherein the piezoelectric layer of the piezoelectric film is a polymer-based piezoelectric composite material having piezoelectric particles in a polymer material.

18. The rollable image display device according to claim 17,
wherein the polymer material of the polymer-based piezoelectric composite material is cyanoethylated polyvinyl alcohol.

19. The rollable electroacoustic transducer according to claim 2,
wherein the vibration plate has a rectangular shape and the convex leaf spring is provided with a longitudinal direction thereof being in parallel to one side of the vibration plate, and
the rollable electroacoustic transducer further has a tubular member in a slit formed on a side surface thereof, in which an end part of the vibration plate in a direction orthogonal to the longitudinal direction of the convex leaf spring is inserted into the tubular member and the tubular member extends in the same direction as the end part.

20. The rollable electroacoustic transducer according to claim 19,
wherein an end part in the longitudinal direction of the convex leaf spring is inserted into the tubular member.
